(19) United States
(12) Patent Application Publication
(10) Pub. No.: US 2002/0050369 A1
(43) Pub. Date: May 2, 2002

(54) Thermal insulation apparatus

(76) Inventors: Ian Budden, Cambridge (GB); Stephen George Offley, Cambridge (GB); David Eric Bull, Cambridge (GB)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/000,588

(22) Filed: Oct. 23, 2001

(30) Foreign Application Priority Data
Oct. 31, 2000 (GB) GB 0026580.1

(51) Int. Cl. H05K 5/06

(52) U.S. Cl. 174/17.05; 174/30

(57) ABSTRACT

Thermally insulating apparatus for housing heat sensitive electronic apparatus, comprises an open-topped box with a detachable lid. A gasket is provided to form a heat seal between the open-topped container and the lid. At least one external surface of the gasket, which is exposed to ambient conditions when the lid is removed from the box, is unreactive to the extent whereby hydrophilic particles (e.g. dust) coming into contact therewith are not contaminated and made hydrophobic. The presence of hydrophobic particles may interfere with processes where the thermally insulating apparatus is deployed, and thus maintaining inherent hydrophilic properties may be important.

### BACKGROUND OF THE INVENTION

The present invention relates to thermal insulation apparatus, particularly but not exclusively apparatus for insulating heat-sensitive instrumentation used to obtain temperature profiles of industrial ovens and the like.

In order to provide a tough coating with the correct physical properties, modern paint and powder coatings undergo a curing process which is both time and temperature dependent. Thus, in order to cure a painted/coated object correctly, both the cure temperature and the cure time need to be controlled. As part of the control, oven temperature recording systems are used to obtain a temperature map or profile of the oven used for the curing process. In the case of conveyor ovens, oven “tracker” systems have been devised which travel through the oven with the objects undergoing the curing process so that object temperature may be monitored continuously.

Typically, an oven tracker system comprises a data recorder housed in a thermally insulating container. Numerous temperature probes are provided for attachment to the object under investigation, and are connected to the recorder through the container walls. One such container has a lid to allow operator access to the data recorder, with a silicone rubber gasket provided to ensure a snug fit between the lid and the remainder of the container.

The present applicant has supplied highly successful oven tracker systems as hereinbefore described for many years. Recently, problems have been encountered with certain processes where the oven tracker systems are deployed. In particular, motor vehicle manufacturers have reported incidents of paint cratering defects in objects (e.g. car body panels) which have been painted and subjected to an oven-curing process in the presence of traditional oven tracker systems. Blame for the cratering phenomena was attributed to hydrophobic insulation dust escaping from the container, landing on the object, and repelling surrounding paint prior to curing. The cratering effect appeared to be exacerbated by the recent introduction of water-based (as opposed to solvent-based) paints, which were actively repelled by the hydrophobic properties of the contaminating dust. The present applicants investigated the insulation material (Microtherm insulation supplied by Microtherm) used in the oven tracker systems, and were surprised to find out that the insulation material was supplied with hydrophilic and not hydrophobic properties. Such a finding was totally unexpected because hydrophilic insulation dust would not give rise to the cratering phenomenon; rather, it would produce a minor defect protruding above surrounding paintwork which could be easily concealed by subsequent polishing and painting operations.

The present applicant has sought to address the cratering phenomenon, and has invented a novel solution to alleviate, even obviate, the problem.

### SUMMARY OF THE INVENTION

In accordance with the present invention, there is provided instrument insulation apparatus comprising: an open-topped container defining an open chamber for receiving a data recorder; a lid for use in combination with the open-topped container to cover the chamber opening; and a gasket for forming a seal between the open-top container and the lid when covering the chamber opening; characterised in that at least one external surface of the gasket is unreactive, whereby hydrophilic dust particles contacting the at least one external surface remain hydrophilic.

The present applicant has examined the hydrophilic Microtherm insulation in its oven tracker systems and against all expectations found that material taken from the top of the barrier adjacent the silicone rubber gasket was hydrophobic. It is believed that a chemical interaction between the hydrophilic insulation and the silicone rubber gasket results in localised conversion to a hydrophobic state. In the light of this discovery, the present applicants have appreciated that any hydrophilic dust particles (from the insulating material or from external dust sources) could be rendered hydrophobic on contact with a silicone rubber gasket. Accordingly, the unreactive or inert at least one surface is intended to prevent conversion of dust particles with a hydrophilic tendency to a hydrophobic tendency. Thus, the at least one surface would be substantially free of exposed silicones capable of contaminating dust through contact. For the purposes of the present invention, the term ‘unreactive’ means that there is substantially no discernible ability to transform hydrophilic properties of dust into hydrophobic properties simply through contamination of the dust by contact with the gasket.

The at least one external surface of the gasket may be exposed to ambient conditions when the lid is removed and the chamber opening uncovered. The at least one surface may extend around the entire periphery of the gasket. The at least one external surface may include a heat resistant barrier layer. For the purposes of the present invention, the term ‘heat resistant’ is defined as being able to withstand 200° C. for 2 hours without discolouration, shrinkage or other visible sign of deterioration. The heat resistant barrier layer may be in the form of a tape or film, and may be wrapped or otherwise applied around a former which may be non-compliant. The tape or film may be bonded to the former using an adhesive. The adhesive may be heat resistant and may comprise acrylic. The heat resistant barrier layer may comprise polyimide, for example Kapton film or tape. Polyimide is believed to be better than PTFE since the latter may cause cratering effects in paintwork. The former may be heat resistant and may be substantially silicone free. For example, the former may comprise polyimide, possibly in a compressed fibrous form.

The non-compliant former may comprise a plurality of parts. In this way, a gasket former for the opening of an open-topped container may be cut from sheet material without strictly having to waste quantities of the latter. For example, in the case of rectangular-box-shaped container, the former may be formed from two “L”-shaped parts, without wasting a rectangular core of sheet material. The parts of the non-compliant former may comprise interengaging or interlocking profiles to give a structural framework when the parts are assembled together. For example, the profiles may provide mortise and tenon couplings, possibly even interlocking mortise and tenon couplings, e.g. jigsaw-type interlocking couplings.

A resilient member may also be provided which, in use, is sandwiched between the non-compliant former and the open-topped container. The resilient member may be wrapped or otherwise covered with a heat resistant barrier layer. The resilient member may comprise a heat resilient material and may be substantially free of silicone. It may perhaps be of fibrous polyimide. The gasket may be received in a locating recess in side walling of the open-top container.

### BRIEF DESCRIPTION OP THE DRAWINGS

An embodiment of the invention will now be described by way of example with reference to the accompanying drawings in which:

FIG. 1 is an exploded perspective view of insulation apparatus embodying the present invention;

FIG. 2 is an enlarged cross-sectional view along AA of side walling of the insulation apparatus of FIG. 1; and

FIG. 3 is a plan view of gasket detail of the apparatus of FIG. 1.

### DESCRIPTION OF SPECIFIC EMBODIMENT

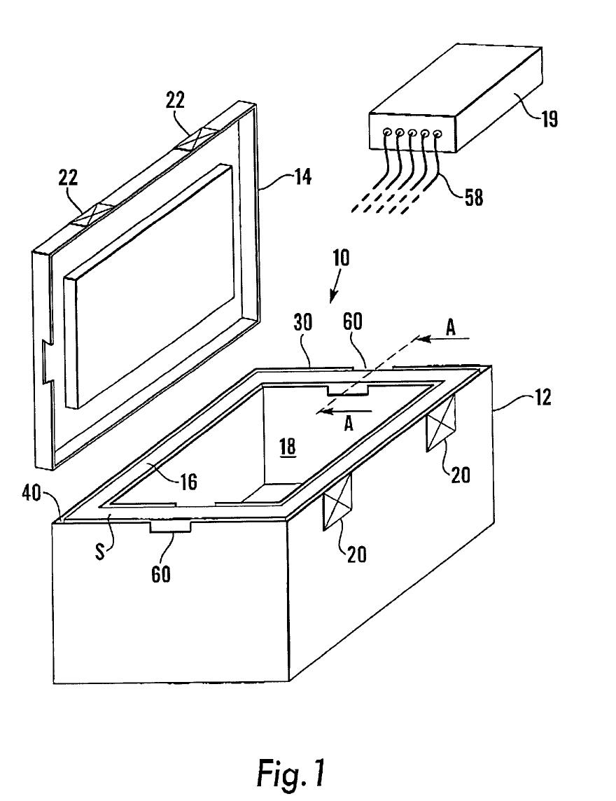

FIG. 1 shows insulation apparatus 10 comprising an open-top container 12 and a corresponding lid 14, and a gasket 16. The open-top container 12 defines an open chamber 18, the opening to which is covered by lid 14 when insulation apparatus 10 is ready for use, i.e. a data recorder 19 housed in chamber 18. The gasket 16 provides a seal between the lid 14 and open-top container 12 when the lid 14 covers the open chamber 18. In fact, over-centre action toggle clamps 20 (only two are shown) are provided on opposite sides of the open-top container 14 to engage corresponding lugs 22 in the lid 14, and thereby compress the gasket 16 between the lid 14 and open container 12. The gasket 16 includes at least one external surface S which is unreactive, whereby hydrophilic dust particles coming into contact with surface “S” remain hydrophilic.

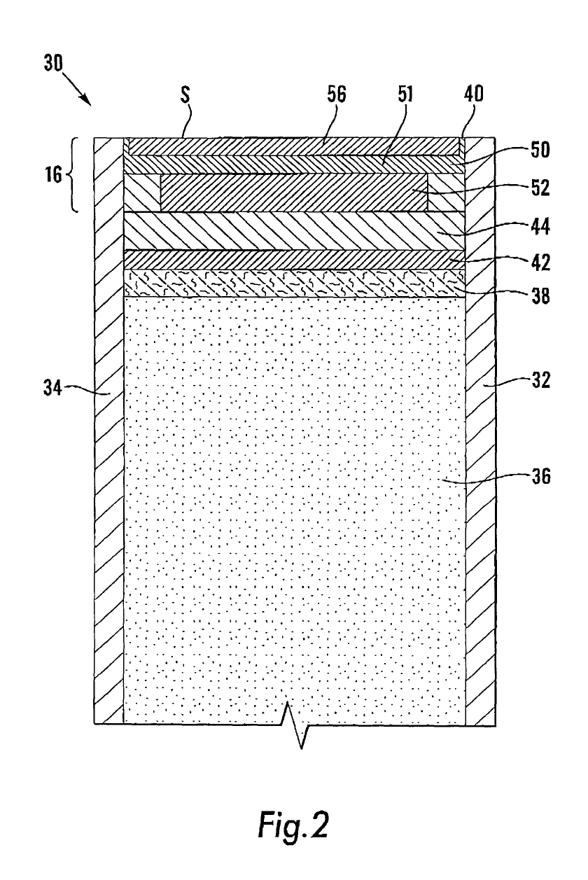

FIG. 2 is a cross sectional view along line AA in FIG. 1 and shows side wall and gasket features in detail. A side wall 30 of the container 12 includes metal inner wall 32 (bordering chamber 18) and outer metal wall 34. The inner and outer walls 32,34 are spaced apart and a hydrophilic Microtherm insulator 36 is provided in the spacing therebetween. The insulator 36 is sealed within the inner and outer walls 32,34 by a fibreglass cloth seal 38, which is epoxy bonded to the metal walls and Microtherm material. The inner and outer walls 32,34 extend above the fibreglass cloth seal 38 defining a recess 40 for receiving gasket 16 and underlying padding or resilient layers 42,44 of soft, felt-like polyimide material. (The padding layers 42,44 may be replaced by a single layer as required).

The gasket 16 comprises two separate members. Upper member 50 comprises a former 51 of polyimide material wrapped in polyimide tape (e.g. Kapton tape), and lower member 52 comprises polyimide material 80% part-wrapped in polyimide tape (e.g. Kapton tape). In each wrapped or part-wrapped member, the polyimide tape is bonded to the polyimide material using an acrylic adhesive. The upper member 50 includes a resilient insert 56 comprising a softer polyimide material, wrapped in polyimide tape (e.g. Kapton tape) as in the upper member 50. Being softer, insert 56 provides a cushion for accommodating cabling 58 passing from the open chamber 18 through the container 12 in the region of cut-outs 60. Such cabling would be used to connect a data recorder 19 in chamber 16 to external thermocouples (not shown).

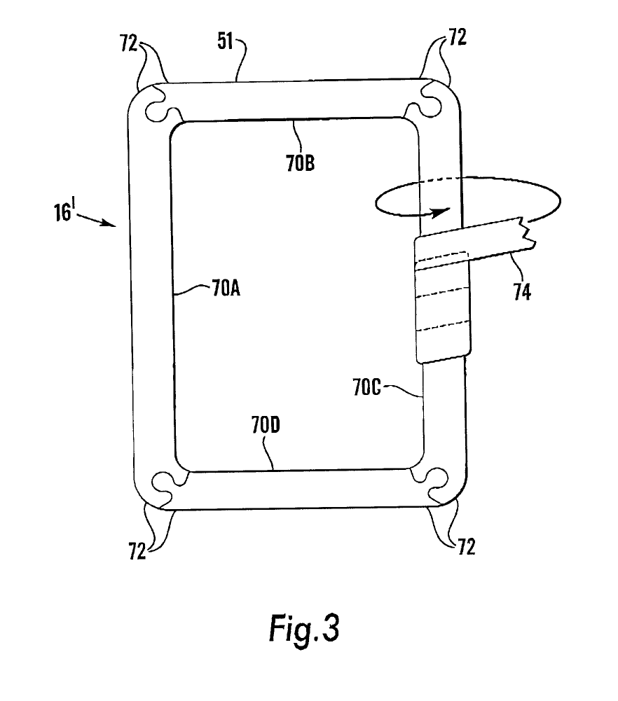

As shown in FIG. 3 the upper member 50 of gasket 16 includes a non-compliant rectangular-frame former 51 comprising elongate members 70A,B,C,D of polyimide fibreboard material. Each elongate member 70A,B,C,D is formed with a pair of interlocking profiles 72 which interengage with corresponding profiles of adjacent members to form a firm framework structure. The long-sided members 70A,C are made from 9 mm thick fibreboard material, whilst the short-sided members 70B,D are made of 6 mm thick fibreboard material. In this way, the short-sided members 70B,D form a recess for receiving the resilient insert 56. The members 70A,B,C,D are wrapped in polyimide tape 74.

In use, external surfaces of the gasket 16 which are exposed to ambient conditions (i.e. upper member 50 and insert 56) are protected by polyimide tape which acts as a barrier layer. The polyimide tape is unreactive in the sense that dust particles (either from within the insulation apparatus or from external sources) which are naturally hydrophilic are not rendered hydrophobic through contact with the gasket. By preventing the generation of hydrophobic dust particles, paint cratering phenomenon may be alleviated or even obviated.

In the claims:

1. Instrument insulation apparatus comprising: an open topped container defining an open chamber for receiving a data recorder; a lid for use in combination with the open-top container to cover the chamber opening; and a gasket for forming a seal between the open-topped container and the lid when covering the chamber opening; characterised in that at least one external surface of the gasket is unreactive to an extent whereby hydrophilic dust particles contacting the at least one external surface remain hydrophilic.

2. Instrument insulation apparatus according to claim 1, in which the at least one external surface of the gasket is exposed to ambient conditions when the lid is removed from the chamber opening.

3. Instrument insulation apparatus according to claim 1, in which the at least one external surface includes a heat resistant barrier layer.

4. Instrument insulation apparatus according to claim 3, in which the heat resistant barrier layer is in a form selected from a tape and a film.

5. Instrument insulation apparatus according to claim 4, in which the tape or film is wrapped around a former.

6. Instrument insulation apparatus according to claim 5, in which the tape or film is bonded to the former using a heat resistant adhesive.

7. Instrument insulation apparatus according to claim 3, in which the heat resistant harrier layer comprises polyimide.

8. Instrument insulation apparatus according to claim 1, in which the gasket is substantially free of silicone, PTFE or any other potential fluoro-carbon-producing materials.

9. Instrument insulation apparatus according to claim 1, further comprising a resilient member sandwiched between the at least one external surface of the gasket and side-walling of the open-top container.

10. Instrument insulation apparatus according to claim 9, in which the resilient member is substantially free of silicone, PTFE or any other potential fluoro-carbon-producing materials.

11. Instrument insulation apparatus according to claim 9, in which the resilient member comprises heat resistant polyimide.

12. A gasket for instrument insulation apparatus comprising a heat resistant body, the heat resistant body being covered with a heat resistant tape or film, the heat resistant tape or film being unreactive to an extent, whereby hydrophilic dust particles coming into contact with the heat-resistant tape remain hydrophilic.
